(19) United States
(12) Patent Application Publication
(10) Pub. No.: US 2002/0148565 A1
(43) Pub. Date: Oct. 17, 2002

(54) Mushroom stem wafer pedestal for improved conductance and uniformity

(75) Inventors: Gerhard Schneider, Cupertino, CA (US); Andrew Nguyen, San Jose, CA (US); Michael Barnes, San Ramon, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 09/834,501

(22) Filed: Apr. 12, 2001

(51) Int. Cl. C23F 1/00; C23C 16/00

(52) U.S. Cl. 156/345.51; 118/728

(57) ABSTRACT

Configurations of semiconductor processing chambers to promote consistency of pressure profiles across the surface of the wafer being processed. One aspect of the chamber configuration is a mushroom-shaped wafer support structure with a broad electrode supported by a relatively narrow vertical stem arising from the bottom wall of the chamber. The stem may be centered under the electrode or, optionally, is offset from its center. Services for the electrode are provided via the narrow vertical stem. Another aspect of the chamber configuration is twin processing regions together in a single chamber, evacuated by a single vacuum pump.

The present invention relates generally to the field of manufacturing semiconductor devices. More particularly, the present invention relates to equipment and processes for supporting a semiconductor wafer inside a processing chamber.

### BACKGROUND OF THE INVENTION

When manufacturing semiconductor devices, uniformity and consistency are imperatives. The various manufacturing steps (etching, deposition, etc.) are carried out under vacuum conditions in the controlled environment provided by specially designed chambers.

The shape and size of a processing chamber affects how the low pressure gasses behave inside it, and thus, affects how the semiconductor work piece is treated by those gasses. Of particular concern is the problem of how to maintain uniformity of pressure across the surface of the work piece. Even the slightest differential of pressure at one point on the work piece relative to another point can make a substantial difference in how consistently the surface of the work piece is transformed by the molecules that come in contact with it. Present day process chamber configurations are afflicted with processing inconsistency due to just such pressure differentials.

Referring to FIG. 1, a structure for supporting a semiconductor wafer in a processing chamber according to the prior art is illustrated. A semiconductor wafer 30 is inserted into a processing chamber 10 where it rests on a cylindrical support structure

The cylindrical support structure 20 takes up the better part of the interior volume of the processing chamber

Gases inside the vacuum chamber 10 are evacuated through the space between the cylindrical support structure 20 and the inner wall of the chamber

The gas then exits the processing chamber 10 via a pumping port that is offset to one side to a vacuum pump (a turbomolecular pump TMP is shown).

This type of processing chamber configuration exhibits a detrimental pressure gradient across the wafer surface. The pressure gradient is produced by the fact that gas molecules in the space just above the cylindrical support structure 20 have very different minimum path lengths to the vacuum chamber, depending upon their starting position above the wafer

The longer the minimum path length to the vacuum pump, the greater the pressure at that location above the wafer.

Referring to FIG. 2, a processing chamber and cylindrical support according to another prior art configuration is illustrated. Inside the processing chamber 40, a semiconductor wafer 70 to be processed is supported on a cylindrical support 50, which is supported by cantilever supports 60 that extend from the walls of the chamber

Although the entrance 80 to the vacuum pump is centered below the wafer 70 and its cylindrical support structure 50, the minimum path length for gas molecules across the surface of the wafer 70 is still not very uniform. Gas molecules near the side of the wafer where the cantilever support 60 is present have a substantially longer minimum path length to the entrance 80 of the vacuum pump (i.e., dodging around the cantilever supports 60) than do the molecules at other points across the wafer

Again, this contributes to anisotropic pressure condition across the surface of the wafer

Another disadvantage of this configuration is that it does not permit z-axis (i.e., along a vertical axis) movement of the cylindrical support structure

Referring to FIG. 3, a cross sectional view of a processing chamber 12 according to still another prior art configuration is illustrated. The chamber 12 has two processing regions 18 for processing two wafers at the same time. The two processing regions 18 are evacuated via a plurality of exhaust ports 31 that are in communication with a circumferential pumping channel 25 formed in the chamber walls.

Referring to FIG. 4, a plan view of the processing chamber of FIG. 3 is illustrated. The exhaust path is shown in this view. The circumferential pumping channels 25 of each processing region 18 are connected to a common vacuum pump via a common exhaust channel

The exhaust channel 19 is connected to the pumping channels 25 of each processing region 18 by exhaust conduits

The exhaust channel 19 is connected to a vacuum pump via an exhaust line (not shown).

Referring to FIG. 5, a cross sectional view of a processing chamber according to yet another prior art configuration is illustrated. The chamber 39 has a processing region 42 for processing a wafer. The processing region 42 is evacuated via a circumferential pumping channel 53 formed in the chamber walls. An exhaust channel 57, connected to the pumping channel 53 of the processing region 42, provides an exhaust connection to a vacuum pump via an exhaust line (not shown).

The configurations of FIGS. 3 to 5 share the same problem as those of FIGS. 1 and 2 in that pressure gradients are induced across the surface of the wafer being processed because of the pronounced asymmetry of minimum path length for molecules at the wafer surface. Offset pump configurations (FIGS. 1 and 3 to 5) and the cantilevered support configurations (FIG. 2) inherently have this problem. The pressure gradient contributes substantially to non-homogeneous processing across the surface of the wafer.

Thus, what is needed is a chamber design that provides a reduced pressure differential across the wafer surface by providing a more uniform minimum path length from the surface of the wafer to the pumping port.

Another challenge for semiconductor processing is how to provide consistent conditions in two processing chambers at the same time so that two semiconductor work pieces may be processed simultaneously. Semiconductor processing technology presently available does not provide consistent conditions between two nominally identical chambers because each of the chambers has its own independent vacuum pump. Subtle differences between how the two vacuum pumps perform are amplified by the gas conduction paths to cause substantial variations in the pressure profile (both spatially and temporally) in the two chambers despite the fact that the control commands for the chambers' operating parameters are the same. This problem is a barrier to increasing production by performing the same processing step on multiple wafers simultaneously.

Thus, what is also needed is a way to maintain consistent pressure profile conditions simultaneously in two process chambers.

### SUMMARY OF THE INVENTION

One aspect of the present invention is to provide enhanced uniformity of process conditions for a semiconductor wafer being processed inside a processing chamber.

It is another aspect of the present invention that more uniform pressure conditions are provided for a semiconductor work piece being processed inside a vacuum chamber.

Another aspect of the present invention is a twin wafer processing chamber that provides for increased throughput of wafers being processed by providing for substantially identical processing conditions for a pair of wafers simultaneously.

It is yet another aspect of the present invention that semiconductor wafer processing chambers are provided having a reduced physical footprint than has been possible in the prior art.

It is a still further aspect of the present invention to provide for substantial identical conditions for plural semiconductor wafers in a processing chamber via design shape, gas conductance, and gas delivery parameters, without resort to active controls to maintain the identical conditions.

It is another aspect of the present invention to provide a wafer support structure that has a support stem, supporting the chuck from below, which is substantially narrower than the chuck.

It is yet another aspect of the present invention to provide a wafer support structure having a chuck with its services being provided via a supporting stem that is substantially narrower than the width of the chuck.

It is another aspect of the present invention to provide a chuck and supporting stem structure that promotes pressure uniformity inside a wafer processing chamber.

It is a further aspect of the present invention that a wafer supporting structure provides for increased chamber volume beneath the chuck so that the volume above the chuck may be reduced while maintaining the same overall chamber volume.

One embodiment of the present invention is a processing chamber that has a wafer support structure having a generally mushroom shape. A broad round chuck for supporting a wafer to be processed is supported from beneath by a stem. The services for the chuck are all provided via the stem. The pumping port for evacuating the chamber is placed substantially beneath the chuck.

The chamber for processing a semiconductor article has a chamber body, a chuck, and a stem. The chamber body has a bottom wall wherein the pumping port is formed. The chuck is located inside the chamber body and has an upper surface and a lower surface that faces the bottom wall. The width of the chuck is sufficient to support the semiconductor article on the upper surface. The stem supports the chuck and extends from the bottom wall of the chamber body to the lower surface of the chuck. The width of the stem is substantially smaller than the width of the chuck.

Others of the above aspects of the present invention are embodied by a chamber for simultaneously processing two semiconductor articles (i.e., wafers) under substantially identical process conditions. The chamber includes chamber body with a pumping port disposed in its bottom wall, and a vacuum pump in fluid communication with the pumping port. A pair of article supports, as well as respective stems supporting those article supports, is disposed in the chamber. Each article support has an upper surface and a lower surface that faces the bottom wall of the chamber body. The stems support their respective article support by extending from the bottom wall of the chamber body to the lower surface of the article support. The article supports are each sufficiently wide to support a semiconductor article on their upper surface. The width of each stem is substantially smaller than the width of its article support.

Still others of the above aspects are embodied by a wafer support assembly for use in supporting a semiconductor wafer in a processing chamber. The wafer support assembly includes a wafer support (i.e., a chuck) and a stem. The wafer support has an upper side that is sufficiently wide to support the semiconductor wafer. The stem extends from a lower side of the wafer support and is substantially smaller in width than the wafer support.

Additional objects and advantages of the present invention will be apparent in the following detailed description read in conjunction with the accompanying drawing figures.

### BRIEF DESCRIPTION OF THE DRAWINGS

FIG. 1 illustrates a partial section view of a process chamber with a cylindrical wafer support structure according to a first prior art configuration.

FIG. 2 illustrates a partial section view of a process chamber with a cantilevered wafer support structure according to a second prior art configuration.

FIG. 3 illustrates a cross sectional view of a processing chamber according to still a third prior art configuration.

FIG. 4 illustrates a plan view of the processing chamber of FIG. 3.

FIG. 5 illustrates a cross sectional view of a processing chamber according to yet a fourth prior art configuration.

FIG. 6 illustrates a partial section view of a process chamber having a configuration according to a first embodiment of the present invention.

FIG. 7 illustrates a partial section view of a process chamber having a configuration according to a second embodiment of the present invention.

FIG. 8 illustrates a partial section view of a dual processing region wafer processing system according to a third embodiment of the present invention.

FIG. 9 illustrates a partial section view of another dual processing region wafer processing system according to a fourth embodiment of the present invention.

FIG. 10 illustrates a partial section view of a wafer support structure consistent with the various embodiments of the present invention.

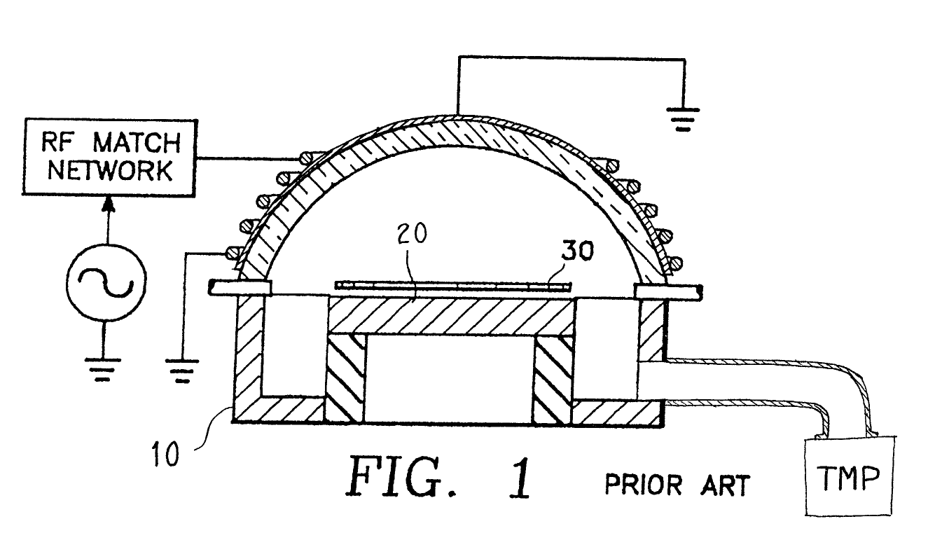

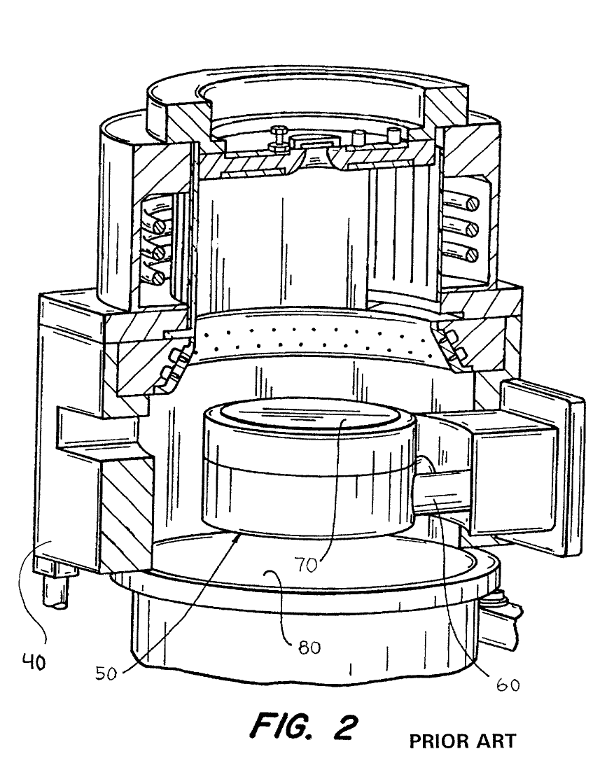

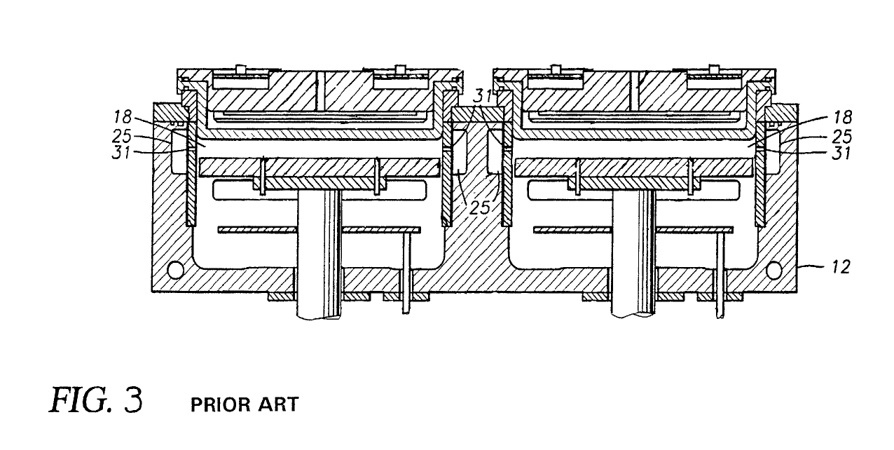

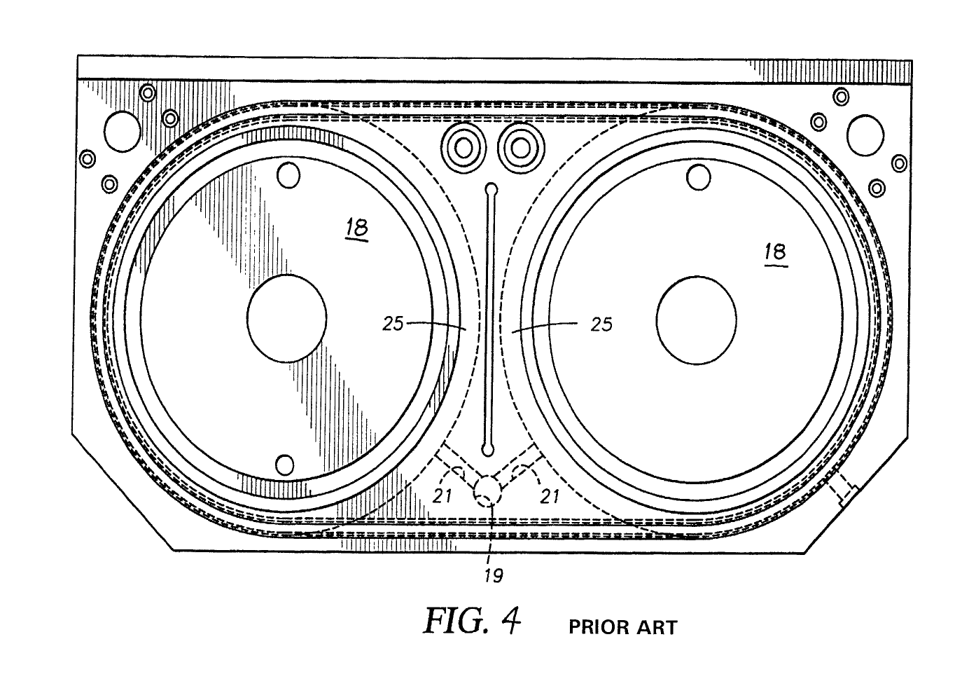

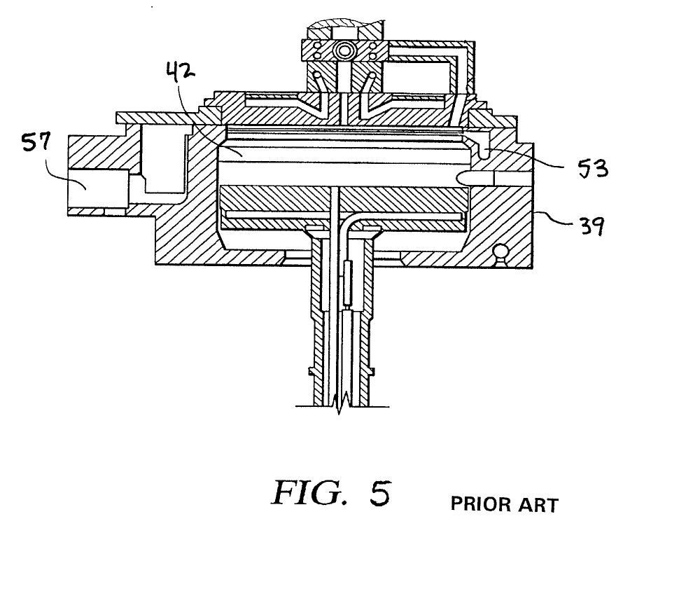

### DETAILED DESCRIPTION OF EMBODIMENTS OF THE INVENTION

A chamber configuration according to the present invention produces at least two salient advantages.

One useful advantage of the novel combination of wafer supporting structure and pump out geometries according to this invention is reduction of the pressure gradient across the surface of wafers being processed in the chamber. This reduction in the pressure gradient is advantageous because it promotes uniformity of processing across the surface of the wafer, thereby increasing the number of highest quality chips produced per wafer.

Another useful advantage of the present invention is the high fluid conductance of the chamber. A wafer supporting structure as disclosed here increases chamber volume beneath the chuck so that the volume above the chuck may be reduced (as the chuck is moved upward in the chamber) while maintaining the same overall chamber volume. This large volume below the chuck happens to be the portion of the chamber through which gas flows to reach the pumping port at the bottom wall of the chamber, and because its volume is larger its conductance as a fluid flow path is larger. With a higher conductance pump out path, the pump can do a better job of maintaining stable pressure at the surface of the wafer.

Additionally, larger interior chamber fluid volume adds to process stability because transients in pressure or flow are easier to manage in a larger volume. Maintaining such a large interior fluid volume without increasing the exterior size of the chamber yields an increased degree of process stability without increasing the footprint (i.e., how much real estate the chamber takes up on a production floor) of the chamber.

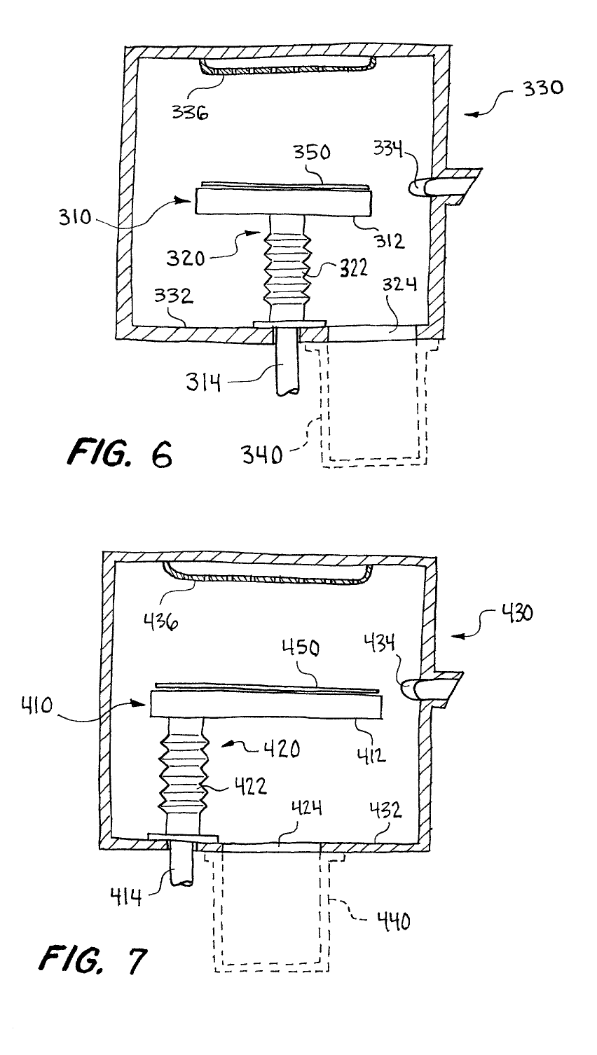

Referring to FIG. 6, a wafer supporting chuck according to an embodiment of the present invention is illustrated. A wafer 350 is inserted into the chamber 330 through a wafer transfer passage 334. After being inserted into the chamber 330, the wafer 350 rests upon the chuck 310. The chuck 310 is supported inside the chamber 330 by a relatively thin stem 320. The stem 320 extends from the bottom surface 312 of the chuck 310 to the bottom wall 332 of the chamber 330. Services are provided to the chuck 310 from outside the chamber via a portion of the stem 314 that extends beyond the bottom wall 332 of the chamber 330. Preferably, the services provided via the external stem portion 314 include RF energy, DC potential for an electrostatic chucking function, helium gas, and coolant.

Another aspect of the stem 320 is that it has bellows 322. The bellows 322 permits the length of the stem 320 to be adjusted from a lowered position to a raised position and back again. In the lowered position, the chuck 310 is positioned so as to permit the wafer 350 to be easily transferred in and out of the chamber 330 via the wafer transfer passage 334. When the wafer 350 is to be processed, the chuck 310 is elevated to the raised position by increasing the length of the stem 320. Raising the chuck 310 places the wafer 350 closer to the shower head 336, located at the top of the chamber 330, that provides reagent gas. This up-and-down, z-axis motion is provided so that during processing the plasma cloud is cannot “see” the wafer transfer passage 334, thus preventing the plasma cloud from being distorted by extending into the wafer transfer passage 334.

Vacuum conditions inside the chamber 330 are maintained by a vacuum pump 340 coupled to the pumping port 324 in the bottom wall 332 of the chamber 330. Importantly, the pumping port 324 is located at least partially beneath the chuck 310. This placement has the effect of substantially equalizing the minimum path lengths for molecules traveling from the space above the wafer 350 to the pumping port 324.

Referring to FIG. 7, a wafer support structure according to another embodiment of the present invention is illustrated. A chuck 410 supports a wafer 450 to be processed inside the chamber. The chuck 410 is, in turn, supported by a relatively thin stem 420, extending from the bottom side 412 of the chuck 410 to the bottom wall 432 of the chamber 430. According to this embodiment, the stem 420 is offset from the center of the chuck 410. This offset configuration makes it possible to place the pumping port, disposed in the bottom wall 432, to be either directly centered or almost centered beneath the chuck 410. This provides an even more enhanced affect of equalizing the minimum path length for gas molecules above the wafer 450 to travel to the pumping port 424, which is evacuated by the vacuum pump 440.

Bellows 422 is provided on the stem 420 to permit the length of the stem 420 to be changed, thus raising and lowering the chuck 410. When the chuck 410 is in a lowered position, the wafer 450 may be inserted into or removed from the chamber 430 via the wafer transfer passage 434. When the wafer 450 is to be processed, the chuck 410 is raised into its raised position, thus placing the wafer 450 into proximity of the showerhead 436, which distributes reagent gases into the space above the wafer 450. This up-and-down, z-axis motion is provided so that during processing the plasma cloud is cannot “see” the wafer transfer passage 434, thus preventing the plasma cloud from being distorted by extending into the wafer transfer passage 434.

Services are provided to the chuck 410 via a portion 414 of the stem 420 that extends beyond the bottom wall 432 of the chamber 430.

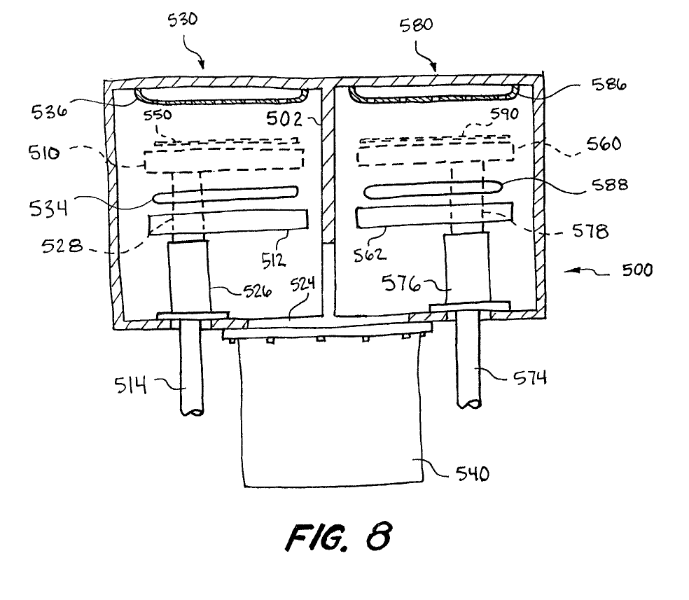

Referring to FIG. 8, a dual processing region alternate embodiment according to the present invention is illustrated. Twin processing regions 530, 580 are disposed adjacent to one another in a single chamber 500 to provide substantially identical processing conditions for a pair of wafers 550, 590. The two processing regions 530, 580 are separated from one another by a partition 502 that extends down at least below the chucks 510, 560.

Each of the processing regions 530, 580 has a respective chuck 510, 560 on which the respective wafers 550, 590 are supported for processing. The illustration of the wafers 550, 590 and their supporting chucks 510, 560 in phantom indicates a raised position for the chucks that places the wafers 550, 590 in close proximity to the gas distribution shower heads 536, 586.

In a lowered position, the chuck 512 is disposed just below the level of the wafer transfer passage 534 through which the wafer 550 passes into and out of the processing region 530. Likewise, the chuck 562 in the adjacent processing region 580 is disposed just below the level of the wafer transfer passage 588 when in its lowered position.

The chuck 512 in the left-hand processing region 530 is supported via a stem 526 having an inner portion 528 that is free to move upwardly thus placing the chuck 510 in its upper position. Likewise the chuck 562 of the right-hand processing region 580 is supported by a stem 576 having an inner portion 578 that is free to move upwardly thus placing the chuck 560 in an upward position. The change of length aspect of the stems 526, 576 is preferably facilitated by respective bellows structures (not shown in this view) that are interior to the illustrated stem portions 526, 528, 576, 578.

According to this embodiment, the stems 526, 576 are offset from the center of their respective chucks 512, 562. This offset configuration maximizes the proportion of the chucks that hang over the pumping port 524.

The two processing regions 530, 580 are pumped to vacuum via a common vacuum pump 540. Gases in the left-hand processing region 530 exit via the pumping port 524 into the vacuum pump 540 and, likewise, the gases of the right-hand processing region 580 are evacuated via the same pumping port 524. Together the two processing region 530, 580 and the common vacuum pump 540 form a wafer processing system. As far as the plasma is concerned, the plasma on each side of the partition 502 sees only its own processing region as though it were still a separate chamber. In each processing region the plasma is created separately. However, the two processing regions 530, 580 have common processing conditions since they are connected to the same exhaust pump 540 and, thus, have the same pressure.

Services to the two chucks 510, 560 are provides via respective stem portions 514, 574 that extend through the bottom wall of the chamber.

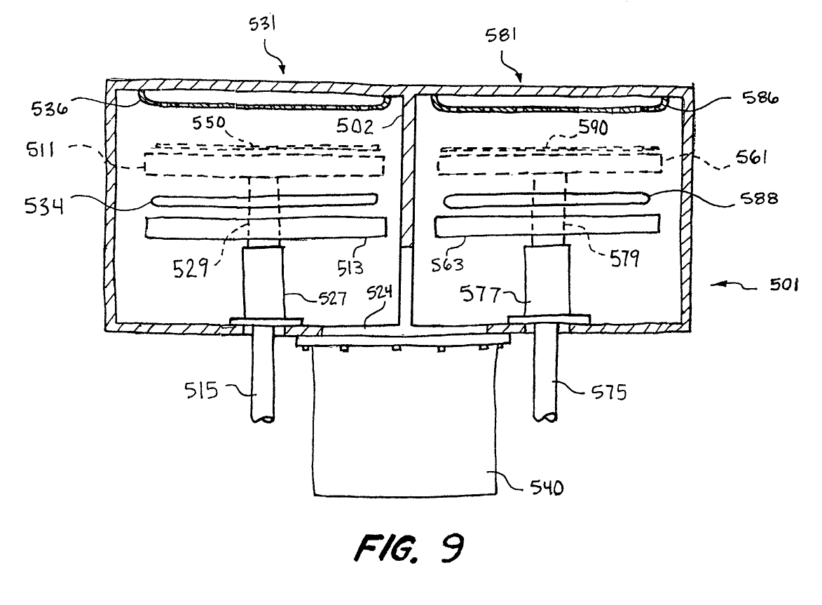

Referring to FIG. 9, another dual processing region alternate embodiment according to the present invention is illustrated. Twin processing regions 531, 581 are disposed adjacent to one another in a single chamber 501 to provide substantially identical processing conditions for a pair of wafers 550, 590. The two processing regions 531, 581 are separated from one another by a partition 502 that extends down at least below the chucks 511, 561.

Each of the processing regions 531, 581 has a respective chuck 511, 561 on which the respective wafers 550, 590 are supported for processing. The illustration of the wafers 550, 590 and their supporting chucks 511, 561 in phantom indicates a raised position for the chucks that places the wafers 550, 590 in close proximity to the gas distribution shower heads 536, 586.

In a lowered position, the chuck 513 is disposed just below the level of the wafer transfer passage 534 through which the wafer 550 passes into and out of the left-hand processing region 531. Likewise, the chuck 563 in the adjacent right-hand processing region 581 is disposed just below the level of the wafer transfer passage 588 when in its lowered position.

The chuck 513 in the left-hand processing region 531 is supported via a stem 527 having an inner portion 529 that is free to move upwardly thus placing the chuck 511 in its upper position. Likewise the chuck 563 of the right-hand processing region 581 is supported by a stem 577 having an inner portion 579 that is free to move upwardly thus placing the chuck 561 in an upward position. The change of length aspect of the stems 527, 577 is preferably facilitated by respective bellows structures (not shown in this view) that are interior to the illustrated stem portions 527, 529, 577, 579.

According to this embodiment, the stems 527, 577 are substantially aligned with the center of their respective chucks 513, 563. This centered stem configuration ensures that a proportion of the chucks hang over the pumping port 524 while simplifying the stem-to-chuck interface. Services to the two chucks 513, 563 are provides via respective stem portions 515, 575 that extend through the bottom wall of the chamber.

The two processing regions 531, 581 are pumped to vacuum via a common vacuum pump 540 through the pumping port 524. Together the two processing region 531, 581 and the common vacuum pump 540 form a wafer processing system. As far as the plasma is concerned, the plasma on each side of the partition 502 sees only its own processing region as though it were still a separate chamber. In each processing region the plasma is created separately. However, the two processing regions 531, 581 have common processing conditions since they are connected to the same exhaust pump 540 and, thus, have the same pressure.

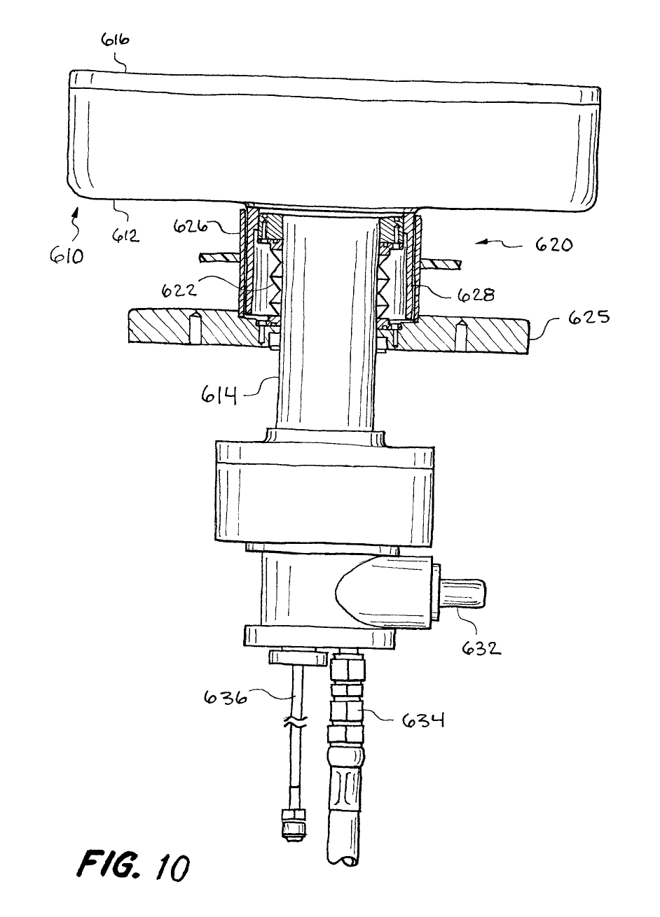

Referring to FIG. 10, a partial section detail view of a chamber support structure according to any of the embodiments of the present invention is illustrated. A chuck 610 is supported by a stem 620. The stem 620 is affixed to the bottom surface 612 of the chuck 610 and has a large flange 625 for affixing the entire assembly to the bottom wall of the vacuum processing chamber (not shown in this view).

The structure of the stem 620 is shown in partial section to illustrate an exemplary configuration for the stem. A bellows 622 is employed to provide a vacuum limit that permits changes in length of the stem between the flange 625 and the bottom surface 612 of the chuck 610. An inner telescope wall 628 is linearly moveable inside an outer telescope wall 626. The telescoped walls 626, 628 surround the bellows 622 to shield it from direct exposure to the space below the chuck 610.

An inner shaft 614 of the stem 620 provides services to the chuck 610. RF energy is supplied to the chuck via an RF connection 632. Fluid couplings 634, 636 provide for coolant and helium gas supply to the chuck 610 for the purpose of cooling the wafer.

On the upper side of the chuck 610, an electrostatic chuck 616 is formed for holding the wafer (not shown in this view) securely in place during processing. DC potential for powering the electrostatic chuck 616 is provided via the inner shaft 614 along with the other services.

The present invention has been described in terms of preferred embodiments, however, it will be appreciated that various modifications and improvements may be made to the described embodiments without departing from the scope of the invention. The present invention is limited only by the appended claims.

What is claimed is:

1. A chamber for processing a semiconductor article, the chamber comprising:
a chamber body having a bottom wall with a pumping port formed therein;
an article support disposed inside the chamber body, the article support comprising:
an upper surface, and
a lower surface facing the bottom wall;
wherein the article support has a first width sufficient to support the semiconductor article on the upper surface; and
a stem extending from the bottom wall of the chamber body to the lower surface of the article support, the stem supporting the article support;
wherein the stem has a second width substantially smaller than the first width.

2. The chamber for processing a semiconductor article of claim 1, wherein the article support is substantially circular, having a center, and wherein the stem connects to the article support substantially at the center.

3. The chamber for processing a semiconductor article of claim 2, wherein the pumping port is located at least partially beneath the article support.

4. The chamber for processing a semiconductor article of claim 1, wherein the article support is substantially circular, having a center, and wherein the stem connects to the article support at a position offset from the center.

5. The chamber for processing a semiconductor article of claim 4, wherein the pumping port is located substantially completely beneath the article support.

6. The chamber for processing a semiconductor article of claim 1, wherein the stem comprises bellows that permits movement of the article support with respect to the bottom wall of the chamber.

7. The chamber for processing a semiconductor article of claim 1, wherein the article support is supplied with a DC potential via the stem.

8. The chamber for processing a semiconductor article of claim 1, wherein the article support is supplied with helium gas, via the stem, to enhance thermal conduction between the article support and the semiconductor wafer.

9. The chamber for processing a semiconductor article of claim 1, wherein internal cooling journals formed in the article support are supplied with coolant via the stem.

10. The chamber for processing a semiconductor article of claim 1, wherein the stem comprises bellows disposed between the article support and the bottom wall of the processing chamber, the bellows permitting linear motion between the article support and the bottom side of the processing chamber along a longitudinal axis of the stem.

11. The chamber for processing a semiconductor article of claim 1, wherein the stem is adapted to couple RF energy to the article support.

12. A processing system for simultaneously processing plural semiconductor articles under substantially identical process conditions, the processing system comprising:
a chamber body having a bottom wall with a pumping port formed therein;
a vacuum pump in fluid communication with the pump port;
plural article supports disposed inside the chamber body, each of the plural article support comprising: an upper surface, and a lower surface facing the bottom wall; and
plural stems, each supporting a respective one of the plural article supports, each of the plural stems extending from the bottom wall to the lower surface of its respective article support;
wherein each of the plural article supports is sufficiently wide to support one of the plural semiconductor articles on its upper surface, and wherein each of the article supports is substantially wider than its respective stem.

13. The processing system of claim 12, wherein the pumping port is located at least partially beneath each of the plural article supports.

14. The processing system of claim 12, wherein each of the plural article supports is supplied, via its respective stem, with DC potential, helium gas, and coolant.

15. The processing system of claim 12, wherein each of the plural stems comprises bellows permitting linear motion, along a longitudinal axis of that stem, of the respective article support with respect to the bottom wall of the chamber body.

16. A processing system for simultaneously processing two semiconductor articles under substantially identical process conditions, the processing system comprising:
a chamber having a first bottom wall with a pumping port formed therein;
a vacuum pump in fluid communication with the pumping port;
a first article support disposed inside the chamber body, the first article support comprising: a first upper surface, and a first lower surface facing the bottom wall;
a first stem supporting the first article support, the first stem extending from the bottom wall to the first lower surface, wherein the first article support is sufficiently wide to support one of the two semiconductor articles on the first upper surface, and the first article support is substantially wider than the first stem;
a second article support disposed inside the chamber body, the second article support comprising: a second upper surface, and a second lower surface facing the bottom wall; and
a second stem supporting the second article support, the second stem extending from the bottom wall to the second lower surface, wherein the second article support is sufficiently wide to support the other of the two semiconductor articles on the second upper surface, and the second article support is substantially wider than the second stem;
wherein the pumping port is located at least partially beneath the first article support and at least partially beneath the second article support.

17. The processing system of claim 16, wherein the first and second article supports each have geometric centers, and wherein the first stem connects to the first article support substantially at its geometric center and the second stem connects to the second article support substantially at its geometric center.

18. The processing system of claim 16, wherein the first and second article supports are each supplied, via their respective stems, with DC potential, helium gas, and coolant.

19. The processing system of claim 16, wherein the first stem comprises bellows permitting linear motion, along a longitudinal axis of the first stem, of the first article support with respect to the bottom wall of the chamber body; and
wherein the second stem comprises bellows permitting linear motion, along a longitudinal axis of the second stem, of the second article support with respect to the bottom wall of the chamber body.
